(19) United States
(12) Patent Application Publication
(10) Pub. No.: US 2025/0147555 A1
(43) Pub. Date: May 8, 2025

(54) ELECTRONIC DEVICE AND PRODUCTION METHOD FOR ELECTRONIC DEVICE

(71) Applicant: Panasonic Intellectual Property Management Co., Ltd., Osaka (JP)

(72) Inventors: Hiroki KAMEZAKI, Osaka (JP); Keita ENDO, Osaka (JP); Junichi HASEGAWA, Osaka (JP); Koki YAMAMOTO, Osaka (JP); Jun TAKAHASHI, Miyagi (JP)

(73) Assignee: Panasonic Intellectual Property Management Co., Ltd., Osaka (JP)

(21) Appl. No.: 19/004,352

(22) Filed: Dec. 29, 2024

Related U.S. Application Data
(63) Continuation of application No. PCT/JP2023/023280, filed on Jun. 23, 2023.

(30) Foreign Application Priority Data
Jul. 14, 2022 (JP) 2022-113383

(51) Int. Cl. G06F 1/16

(52) U.S. Cl. CPC G06F 1/1675

(57) ABSTRACT

An electronic device according to the present disclosure includes: a first substrate on which a first connector is mounted; a second substrate that is disposed with a gap with respect to the first substrate in a first direction, and on which a second connector is mounted; and a flexible substrate having one end and another end, with the one end being connected to the first connector, and the other end being connected to the second connector. The first connector and the second connector face each other in the first direction. The flexible substrate further includes a first bent portion, and a second bent portion that is positioned on a side nearer to the other end than the first bent portion. The flexible substrate extending from the first connector is bent at the first bent portion toward one side in a second direction that is orthogonal to the first direction, and extends further toward the one side in the second direction with respect to the first substrate. The flexible substrate extending from the second connector is bent at the second bent portion toward the other side in the second direction, and extends further toward the other side in the second direction with respect to the second substrate.

### TECHNICAL FIELD

The present disclosure relates to an electronic device including two connectors connected by a flexible substrate.

### BACKGROUND ART

PTL 1 and PTL 2 disclose electronic devices in which a flexible substrate connecting two connectors are disposed by bending.

### CITATION LIST

### Patent Literature

PTL 1: International Publication No. 2009/057546

PTL 2: Unexamined Japanese Patent Publication No. 2009-124402

### SUMMARY OF THE INVENTION

An object of the present disclosure is to provide an electronic device capable of suppressing an increase in the size of the gap between two connectors while allowing a flexible substrate connecting the two connectors to be disposed by bending.

An electronic device according to one aspect of the present disclosure includes:
a first substrate on which a first connector is mounted;
a second substrate that is disposed with a gap with respect to the first substrate in a first direction, and on which a second connector is mounted; and
a flexible substrate having one end and another end, with the one end being connected to the first connector, and the other end being connected to the second connector, in which
the first connector and the second connector face each other in the first direction,
the flexible substrate further includes a first bent portion, and a second bent portion that is positioned on a side nearer to the other end than the first bent portion,
the flexible substrate extending from the first connector is bent at the first bent portion toward one side in a second direction that is orthogonal to the first direction, and extends further toward the one side in the second direction with respect to the first substrate, and
the flexible substrate extending from the second connector is bent at the second bent portion toward another side in the second direction, and extends further toward the other side in the second direction with respect to the second substrate.

A production method for an electronic device according to an aspect of the present disclosure includes:
a step of attaching a first substrate to a housing;
a step of connecting one end of a flexible substrate to a first connector mounted on the first substrate;
a step of connecting another end of the flexible substrate to a second connector mounted on a second substrate, in which
the flexible substrate includes:
one principal surface;
another principal surface that is on a rear side of the one principal surface;
at least one one-side bent portion having a concave on the one principal surface;
a first other-side bent portion provided between the one-side bent portion and the one end, and having a concave on the other principal surface; and
a second other-side bent portion provided between the one-side bent portion and the other end, and having a concave on the other principal surface,
after the first substrate is attached to the housing and the one end is connected to the first connector, the one principal surface or the other principal surface of the flexible substrate faces the housing, and
the production method further includes a step of attaching the second substrate next to the first substrate in the housing so that the first connector and the second connector face each other in a first direction, after the first substrate is attached to the housing, the one end is connected to the first connector, and the other end is connected to the second connector, in which
when the second substrate is attached to the housing, the second substrate is attached to the housing by being brought nearer to the first substrate in the first direction in such a manner that the one-side bent portion is positioned on one side in a second direction orthogonal to the first direction, with respect to the first substrate, and the second other-side bent portion is positioned on another side in the second direction with respect to the first substrate.

According to the present disclosure, it is possible to provide an electronic device capable of suppressing an increase in the size of the gap between two connectors while allowing a flexible substrate connecting the two connectors to be disposed by bending.

### BRIEF DESCRIPTION OF THE DRAWINGS

FIG. 1 is a perspective view of one example of an electronic device according to an exemplary embodiment of the present disclosure.

FIG. 2 is a perspective view of a part of a lower housing of the electronic device illustrated in FIG. 1.

FIG. 3 is a perspective view of the lower housing in FIG. 2, in a view from the opposite side.

FIG. 4 is a cross-sectional view of the lower housing in FIG. 3, taken along line A-A.

FIG. 5 is a diagram for explaining a process of producing the electronic device, and is a perspective view with a first substrate attached to the lower housing.

FIG. 6 is a perspective view subsequent to FIG. 5, with a flexible substrate connected to the first substrate.

FIG. 7 is a perspective view subsequent to FIG. 6, with the flexible substrate being about to be connected to a second substrate.

FIG. 8 is a flowchart for explaining a production method for the electronic device.

### DESCRIPTION OF EMBODIMENT

### Background of Present Disclosure

In an electronic device, when a flexible substrate is used to connect two connectors facing each other, the length of the flexible substrate is adjusted to the distance between the two connectors. For example, the length of the flexible substrate is set to the same size as the distance between the two connectors.

However, when the length of the flexible substrate is adjusted to the distance between the two connectors, the following problem may occur. Connectors are usually mounted on a substrate. At that time, due to factors such as a tolerance, the positions where two connectors are mounted may become offset in lateral directions. In such a case, the relative positions of the two connectors with respect to each other may become offset in the lateral directions, and cause the distance between the two connectors to become longer than expected. The flexible substrate may then fail to be inserted sufficiently into the connectors, and may result in a defective contact. In other words, the flexible substrate may not be able to cope with such a positional displacement of two connectors.

As a solution to this problem, it is conceivable to use a flexible substrate having a length sufficiently longer than the distance between the two connectors. With this, even if the distance between the two connectors becomes longer than expected, the flexible substrate can be inserted sufficiently into each of the connectors.

However, when a flexible substrate sufficiently longer than the distance between the two connectors is used, the flexible substrate connected between the two connectors becomes bent. When different portions of a bent flexible substrate come into contact with each other, the flexible substrate may become damaged. Therefore, it is necessary to increase the distance between the two connectors in order to ensure a space for enabling the flexible substrate to be bent without any portion coming into contact with another. As a result, in the electronic device, a larger space is required to dispose the substrate having the connectors mounted thereon, and the flexible substrate connecting the connectors.

The inventors of the present invention have found out that the distance between the two connectors can be shortened by bending a portion of the flexible substrate extending from one of the two connectors in a direction opposite to a direction for bending another portion extending from the other one of the two connectors, and have arrived at the following disclosure.

One exemplary embodiment of the present disclosure will now be described with reference to the accompanying drawings. Note that the following description is merely exemplary in nature, and is not intended to limit the scope of, applications of, or use of the present disclosure. Moreover, the drawings are schematic representations, and the ratios between dimensions or the like do not necessarily match the actual dimensions.

The terms “first”, “second”, and the like used herein are only for the purpose of description, and should not be understood as explicitly or implicitly indicating relative importance or a priority of technical features. The presence of the limitations as “first” and “second” indicate, explicitly or implicitly, that there is one or more of such features.

### Exemplary Embodiment

### [General Configuration]

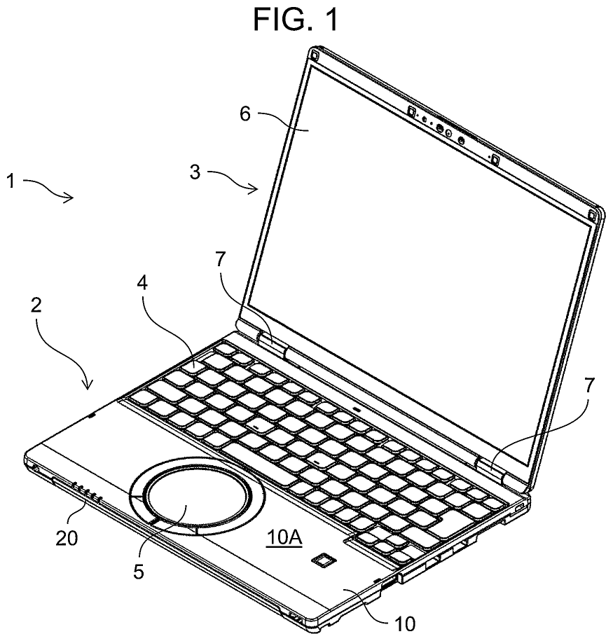

FIG. 1 is a perspective view of one example of an electronic device according to an exemplary embodiment of the present disclosure.

In this exemplary embodiment, electronic device 1 is a notebook personal computer (laptop PC), as illustrated in FIG. 1.

Electronic device 1 includes housing 2 and housing 3. Each of housings 2, 3 has a thin box-shaped outer shell, and has a rectangular shape in a view from the upper surface side.

Housing 2 houses keyboard 4 and touch pad 5. Housing 3 houses liquid crystal panel 6. In the present description, keyboard 4 and touch pad 5 are sometimes referred to as input units 4, 5, and liquid crystal panel 6 is sometimes referred to as display 6.

Housings 2, 3 are connected via hinge 7. Hinge 7 is provided at an end of housing 2 in the depth direction. Hinge 7 rotatably connects housings 2, 3. At least one of housings 2, 3 is enabled to rotate about hinge 7, and electronic device 1 is enabled to be opened and closed. Specifically, electronic device 1 can be brought into an open state and a closed state about hinge 7. The “open state” is a state in which housings 2, 3 are separated from each other and input units 4, 5 and display 6 are exposed. The “closed state” is a state in which housings 2, 3 are disposed in a manner facing each other, and input units 4, 5 and display 6 face each other, without input units 4, 5 and display 6 exposed.

Housing 2 includes upper housing 10 and lower housing 20. Upper housing 10 and lower housing 20 are engaged with each other. In this exemplary embodiment, upper housing 10 and lower housing 20 are made of a metal material. One example of the metal material includes a magnesium alloy.

Upper housing 10 faces housing 3 when electronic device 1 is in the closed state. Lower housing 20 is positioned on the opposite side of housing 3 with respect to upper housing 10, when electronic device 1 is in the closed state. Upper housing 10 and lower housing 20 are fixed to each other with a plurality of screws along the outer peripheral part of housing 2.

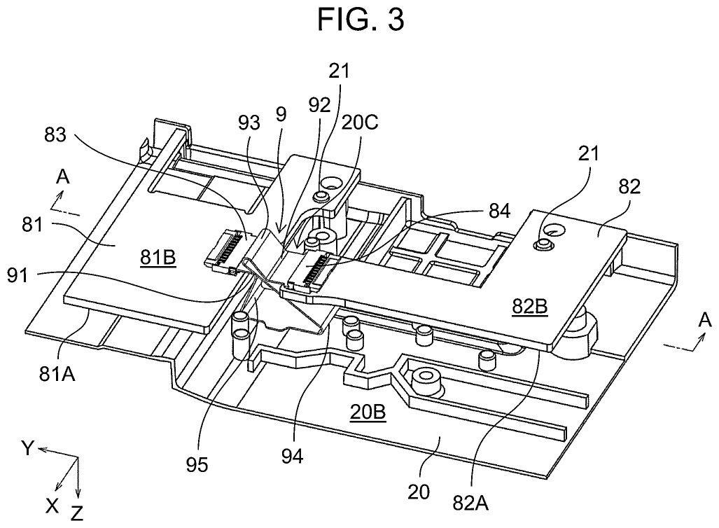

A space between upper housing 10 and lower housing 20 forms the internal space of housing 2. Keyboard 4 and touch pad 5 are housed inside this internal space. Substrates 81, 82 and flexible substrate 9, to be described later, are also housed inside this internal space (see FIG. 3).

Upper housing 10 has outer surface 10A. Outer surface 10A faces liquid crystal panel 6 of housing 3 when electronic device 1 is in the closed state.

Outer surface 10A has two openings. Through the larger one of the two openings, keyboard 4 is exposed to the outside of housing 2. Through the smaller one of the two openings, touch pad 5 is exposed to the outside of housing 2.

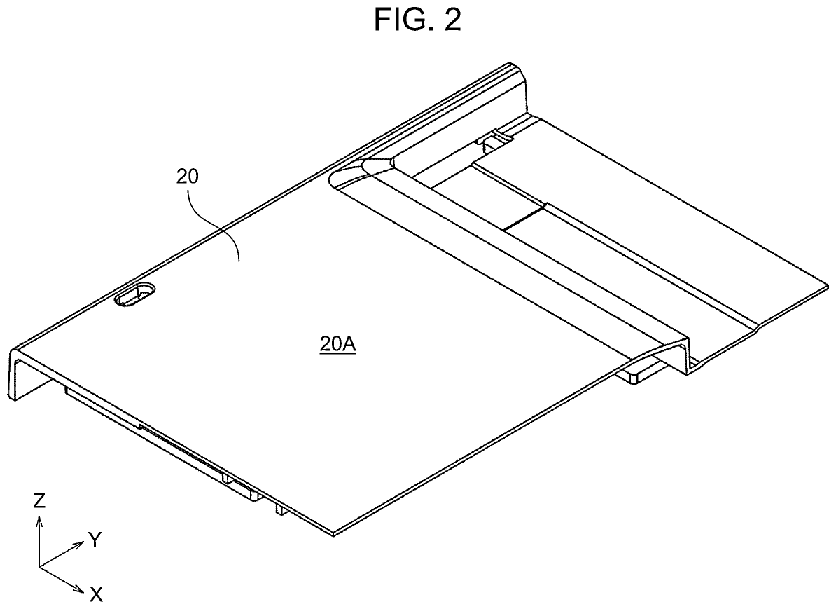

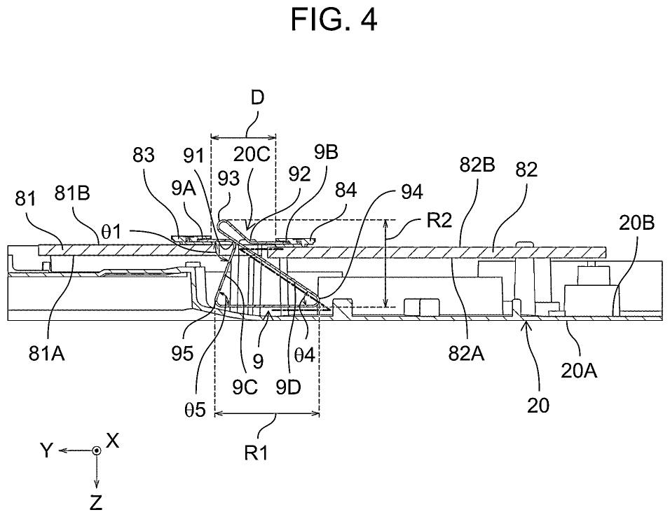

FIG. 2 is a perspective view of a part of the lower housing of the electronic device illustrated in FIG. 1. FIG. 3 is a perspective view of the lower housing in FIG. 2, in a view from the opposite side. FIG. 4 is a cross-sectional view of the lower housing in FIG. 3, taken along line A-A. The X, Y, and Z directions in FIG. 2 and the subsequent drawings correspond to a width direction, a depth direction, and a height direction of housing 2, respectively. The X direction, the Y direction, and the Z direction are orthogonal to one another. The X direction is one example of a third direction. The Y direction is one example of a first direction. The Z direction is one example of a second direction.

As illustrated in FIG. 2, lower housing 20 has outer surface 20A. Outer surface 20A serves as a setting surface when electronic device 1 is placed on a desk or the like.

As illustrated in FIGS. 3 and 4, substrates 81, 82 and flexible substrate 9 are housed in the internal space of housing 2. The internal space of housing 2 faces inner surface 20B of lower housing 20, which is a rear surface of outer surface 20A of lower housing 20. Substrates 81, 82 are fixed to lower housing 20 by screws 21, for example. Substrate 81 is one example of a first substrate. Substrate 82 is one example of a second substrate.

Substrate 82 is disposed with respect to substrate 81 with gap 20C therebetween in the Y direction. In other words, substrates 81, 82 face each other with gap 20C therebetween in the Y direction.

Principal surface 81A of substrate 81 and principal surface 82A of substrate 82 face inner surface 20B of lower housing 20 in the Z direction. Principal surface 81B of substrate 81 is a surface on the rear side of principal surface 81A. Principal surface 82B of substrate 82 is a surface on the rear side of principal surface 82A.

In this exemplary embodiment, the length of substrate 81 in the Z direction is the same as the length of substrate 82 in the Z direction. In other words, the thickness of substrate 81 is the same as the thickness of substrate 82. Note that, however, the thickness of substrate 81 may be different from the thickness of substrate 82.

The position of substrate 81 in the Z direction is offset from the position of substrate 82 in the Z direction. In this exemplary embodiment, substrate 82 is positioned on one side in the Z direction, with respect to substrate 81. In other words, substrate 81 is positioned on the other side in the Z direction with respect to substrate 82. One side in the Z direction herein is a side to which the arrow indicating the Z direction is pointing, in the drawings, and the other side in the Z direction is the opposite side of the side to which the arrow indicating the Z direction is pointing, in the drawings. In other words, when substrate 82 is positioned on the one side in the Z direction with respect to substrate 81, substrate 82 is positioned closer to inner surface 20B of lower housing 20 than substrate 81, in the Z direction. When substrate 81 is positioned on the other side in the Z direction with respect to substrate 82, substrate 81 is positioned farther away from inner surface 20B of lower housing 20 than substrate 82, in the Z direction.

That is, in this exemplary embodiment, principal surface 81B of substrate 81 is positioned farther away from inner surface 20B of lower housing 20 than principal surface 82B of substrate 82. In this exemplary embodiment, the level difference between principal surface 81B of substrate 81 and principal surface 82B of substrate 82, in other words, the distance in the Z direction between principal surface 81B and principal surface 82B is 2.5 (mm). Note that this level difference is not limited to 2.5 (mm).

Alternatively, substrate 82 may be positioned on the other side in the Z direction with respect to substrate 81, oppositely to the configuration described above.

Furthermore, the position of substrate 81 in the Z direction may also be the same as the position of substrate 82 in the Z direction. As mentioned earlier, substrate 81 has the same thickness as substrate 82. In such a configuration, the position of principal surface 81A of substrate 81 in the Z direction therefore becomes the same as the position of principal surface 81A of substrate 82 in the Z direction. In this case, the position of principal surface 81B of substrate 81 in the Z direction is also the same as the position of principal surface 82B of substrate 82 in the Z direction.

Note that the position of substrate 81 in the Z direction may be substantially the same as the position of substrate 82 in the Z direction by permitting a dimensional tolerance, a geometric tolerance, or the like of substrates 81, 82.

Connector 83 is mounted on principal surface 81B of substrate 81. Connector 84 is mounted on principal surface 82B of substrate 82. In this exemplary embodiment, connector 83 is made of resin. Connector 83 is one example of a first connector. Connector 84 is one example of a second connector.

Note that connector 83 may be mounted on principal surface 81A of substrate 81. Furthermore, connector 84 may be mounted on principal surface 82B of substrate 82.

Connector 83 faces connector 84 in the Y direction. The relative positional relationship between connectors 83, 84 in the Z direction is determined by the positions of substrates 81, 82, on which connectors 83, 84 are mounted, in the Z direction. In this exemplary embodiment, connector 83 is mounted on principal surface 81B of substrate 81. Furthermore, connector 84 is mounted on principal surface 82B of substrate 82. The position of principal surface 81B of substrate 81 in the Z direction is farther away from inner surface 20B of lower housing 20 than the position of principal surface 82B of substrate 82 in the Z direction. As described above, in this exemplary embodiment, the position of connector 83 in the Z direction is farther away from inner surface 20B of lower housing 20 than the position of connector 84 in the Z direction.

Flexible substrate 9 is a printed substrate having a structure including a thin resin film, such as polyimide, formed on a conductor foil. Flexible substrate 9 is flexible and bendable.

As illustrated in FIG. 4, one end 9A of flexible substrate 9 is connected to connector 83. Other end 9B of flexible substrate 9 is connected to connector 84. As a result, flexible substrate 9 electrically connects substrates 81, 82.

As illustrated in FIGS. 3 and 4, flexible substrate 9 has five bent portions. The five bent portions are first bent portion 91, second bent portion 92, third bent portion 93, fourth bent portion 94, and fifth bent portion 95.

First bent portion 91 is positioned closest to one end 9A of flexible substrate 9, among the five bent portions of flexible substrate 9. Second bent portion 92 is positioned closest to other end 9B of flexible substrate 9, among the five bent portions of flexible substrate 9. That is, second bent portion 92 is positioned closer to other end 9B than first bent portion 91. Third bent portion 93 is positioned between first bent portion 91 and second bent portion 92. Fourth bent portion 94 is positioned between third bent portion 93 and first bent portion 91. Fifth bent portion 95 is positioned between first bent portion 91 and fourth bent portion 94. As described above, the five bent portions of flexible substrate 9 are positioned in the order of first bent portion 91, fifth bent portion 95, fourth bent portion 94, third bent portion 93, and second bent portion 92, in the direction from one end 9A toward other end 9B of flexible substrate 9.

Third bent portion 93 is positioned on the other side in the Z direction with respect to substrate 82. That is, third bent portion 93 is positioned on the opposite side of inner surface 20B of lower housing 20, with respect to substrate 82.

Third bent portion 93 is positioned closer to connector 83 than first bent portion 91 in the Y direction. In other words, third bent portion 93 is positioned between first bent portion 91 and connector 83 in the Y direction. Third bent portion 93 is positioned on the other side in the Z direction with respect to first bent portion 91. In other words, third bent portion 93 is positioned on the opposite side of inner surface 20B of lower housing 20, with respect to first bent portion 91, in the Z direction.

Fourth bent portion 94 is positioned on the one side in the Z direction with respect to substrate 82. That is, fourth bent portion 94 is positioned on the side of inner surface 20B of lower housing 20, with respect to substrate 82. In other words, fourth bent portion 94 is positioned between substrate 82 and inner surface 20B in the Z direction.

Fifth bent portion 95 is positioned on the one side in the Z direction with respect to substrate 81. That is, fifth bent portion 95 is positioned on the side of inner surface 20B of lower housing 20, with respect to substrate 81. In other words, fifth bent portion 95 is positioned between substrate 81 and inner surface 20B in the Z direction.

Flexible substrate 9 extending from connector 83 extends in a direction opposite to the Y direction toward connector 84, is bent toward the one side in the Z direction at first bent portion 91, passes through gap 20C between substrates 81, 82, extends toward the one side in the Z direction with respect to substrate 81, and reaches fifth bent portion 95. The direction opposite to the Y direction is a direction opposite to the direction of the arrow indicating the Y direction, in each of the drawings.

Flexible substrate 9 extending from connector 84 extends in the Y direction toward connector 83, is bent to the other side in the Z direction at second bent portion 92, extends to the other side in the Z direction with respect to substrate 82, and reaches third bent portion 93. The Y direction is the direction of the arrow indicating the Y direction, in each of the drawings. That is, as illustrated in FIG. 4, the Y direction is a direction from substrate 82 to substrate 81.

That is, in flexible substrate 9, the portion extending from connector 83 mounted on substrate 81 and the portion extending from connector 84 mounted on substrate 82 bend in opposite directions.

Flexible substrate 9 extending from second bent portion 92 to the other side in the Z direction with respect to substrate 82 and reaching third bent portion 93 is bent at third bent portion 93 toward the one side in the Z direction, passes through gap 20C between substrates 81, 82, extends toward the one side in the Z direction with respect to substrate 82, and reaches fourth bent portion 94.

In this exemplary embodiment, among substrates 81, 82, fourth bent portion 94 is positioned on the side of substrate 82 in the Y direction. By contrast, among substrates 81, 82, fifth bent portion 95 is positioned on the side of substrate 81 in the Y direction.

In this exemplary embodiment, the position of fourth bent portion 94 in the Z direction is at the same as the position of fifth bent portion 95 in the Z direction, and flexible substrate 9 between fourth bent portion 94 and fifth bent portion 95 extends straight along the Y direction.

Note that the position of fourth bent portion 94 in the Z direction may be different from the position of fifth bent portion 95 in the Z direction. With such a configuration, flexible substrate 9 between fourth bent portion 94 and fifth bent portion 95 extends straight along a direction inclined with respect to the Y direction. Furthermore, flexible substrate 9 may also be bent between fourth bent portion 94 and fifth bent portion 95.

In this exemplary embodiment, flexible substrate 9 extending from connector 83 extends in the direction opposite to the Y direction, and reaches first bent portion 91. First bent portion 91 is bent at an acute angle. That is, angle θ1 is an acute angle. With this, as portion 9C between first bent portion 91 and fifth bent portion 95 of flexible substrate 9 extends further toward the one side in the Z direction, portion 9C also shifts to the Y direction (more specifically, in the direction from substrate 82 to substrate 81 along the Y direction). Portion 9C is a portion that extends from first bent portion 91 toward the one side in the Z direction, with respect to substrate 81 through gap 20C, and reaches fifth bent portion 95. Fifth bent portion 95 is bent at an acute angle. That is, angle θ5 is an acute angle. As described above, as illustrated in FIG. 4, flexible substrate 9 extends from fifth bent portion 95 toward fourth bent portion 94 along the direction opposite to the Y direction.

As described above, in a view from the X direction, a portion of flexible substrate 9 extending from connector 83 through first bent portion 91 and fifth bent portion 95, and then extending from fifth bent portion 95 delineates a Z shape. Specifically, in a view from the side in front of the paper surface toward behind the paper surface of FIG. 4, the portion delineates a Z shape.

In this exemplary embodiment, flexible substrate 9 extends from connector 84 in the Y direction, and reaches second bent portion 92. As portion 9D between third bent portion 93 and fourth bent portion 94 of flexible substrate 9 extends further toward the one side in the Z direction, portion 9D shifts to the direction opposite to the Y direction (more specifically, in direction from substrate 81 to substrate 82 along the Y direction). Portion 9D is a portion that extends from third bent portion 93, through gap 20C toward the one side in the Z direction with respect to substrate 82, and reaches fourth bent portion 94. Fourth bent portion 94 is bent at an acute angle. That is, angle θ4 is an acute angle. As described above, flexible substrate 9 extends from fourth bent portion 94 toward fifth bent portion 95 along the Y direction.

As described above, in a view from the X direction, a portion of flexible substrate 9 extending from connector 84 through second bent portion 92 and fourth bent portion 94, and then extending from fourth bent portion 94 delineates a Z shape. Specifically, in a view from behind the paper surface toward the side in front of the paper surface of FIG. 4, the portion delineates a Z shape. This portion is indicated by a one-dot chain line in FIG. 4.

In this exemplary embodiment, distance D between connector 83 and connector 84 in the Y direction is 10 (mm) or less. Preferably, distance D is 7 (mm) or less. More preferably, distance D is 4 (mm) or less. In this exemplary embodiment, distance D is 6.7 (mm). Distance D may also be longer than 10 (mm).

In this exemplary embodiment, the length of flexible substrate 9 is set to 45 (mm). In this exemplary embodiment, range R1 where flexible substrate 9 is present in the Y direction is 11.5 (mm). In this exemplary embodiment, range R2 where flexible substrate 9 is present the Z direction is 9 (mm). That is, in this exemplary embodiment, flexible substrate 9 having a length of 45 (mm) is housed within a range a length of 11.5 (mm) in the Y direction and a length of 9 (mm) in the Z direction, in a view from the X direction. Note that the ranges described above may be any ranges other than those described above, and the length of flexible substrate 9 may be a length other than 45 (mm).

### [Production Method]

A production method for electronic device 1 according to this exemplary embodiment will now be described with reference to FIGS. 5 to 8 and FIG. 2.

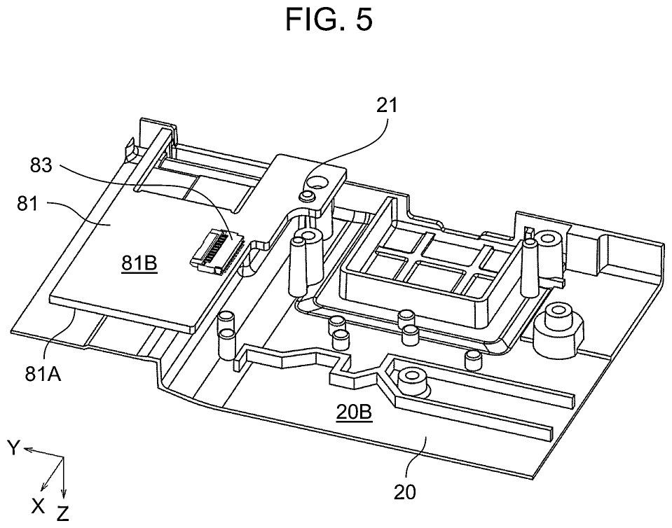

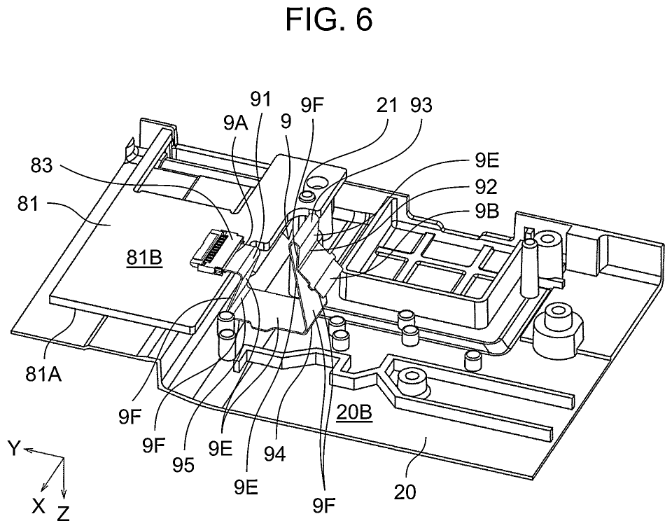

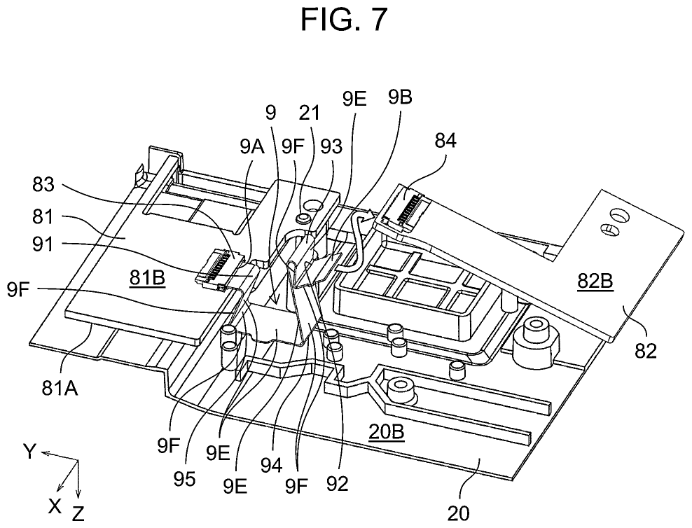

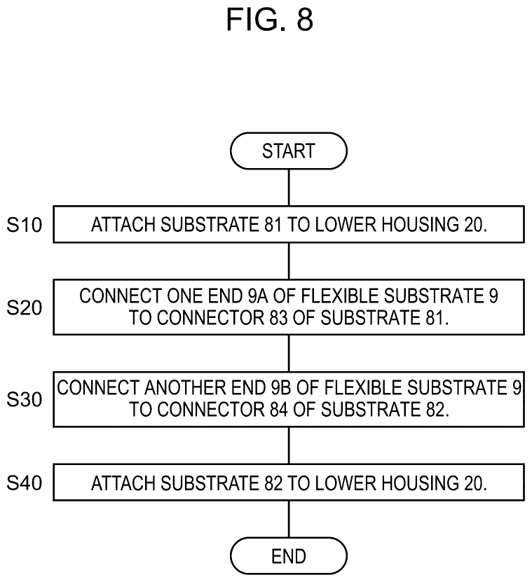

FIG. 5 is a diagram for explaining the process of producing the electronic device, and is a perspective view with the first substrate attached to the lower housing. FIG. 6 is a perspective view subsequent to FIG. 5, with the flexible substrate connected to the first substrate. FIG. 7 is a perspective view subsequent to FIG. 6, with the flexible substrate being about to be connected to the second substrate. FIG. 8 is a flowchart for explaining the production method for the electronic device.

As illustrated in FIG. 8, to begin with, a step of attaching substrate 81 having connector 83 mounted thereon, to lower housing 20 is performed (S10, see FIG. 5). For example, substrate 81 is fixed to lower housing 20 with screws 21. Lower housing 20 is one example of a housing.

Next, a step of connecting one end 9A of flexible substrate 9 to connector 83 is performed (S20, see FIG. 6). Specifically, one end 9A of flexible substrate 9 is inserted into connector 83.

Next, a step of connecting other end 9B of flexible substrate 9 to connector 84 mounted on substrate 82 is performed (S30, see FIG. 7). Specifically, as indicated by the arrow in FIG. 7, other end 9B of flexible substrate 9 is inserted into connector 84.

Note that the three steps S10, S20, and S30 described above may be performed in a different order. For example, substrate 81 may be attached to lower housing 20 after one end 9A of flexible substrate 9 is connected to connector 83. As another example, one end 9A of flexible substrate 9 may be connected to connector 83 after other end 9B of flexible substrate 9 is connected to connector 84.

As illustrated in FIGS. 6 and 7, flexible substrate 9 has one principal surface 9E and other principal surface 9F. Other principal surface 9F is a surface on the rear side of one principal surface 9E.

With substrate 81 attached to lower housing 20 and one end 9A connected to connector 83, that is, in the state illustrated in FIG. 6, other principal surface 9F of flexible substrate 9 faces lower housing 20, and one principal surface 9E of flexible substrate 9 faces the opposite side of lower housing 20. In other words, in the state illustrated in FIG. 6, other principal surface 9F faces the one side in the Z direction, and one principal surface 9E of flexible substrate 9 faces the other side in the Z direction.

Flexible substrate 9 has five bent portions. The five bent portions are first bent portion 91, second bent portion 92, third bent portion 93, fourth bent portion 94, and fifth bent portion 95. Each of second bent portion 92, fourth bent portion 94, and fifth bent portion 95 has the concave on one principal surface 9E. Fourth bent portion 94 and fifth bent portion 95 are examples of a one-side bent portion. Each of first bent portion 91 and third bent portion 93 has the concave on other principal surface 9F. First bent portion 91 is provided between one end 9A and fifth bent portion 95, which is a one-side bent portion. First bent portion 91 is one example of a first other-side bent portion. Third bent portion 93 is provided between other end 9B and fourth bent portion 94, which is a one-side bent portion. Third bent portion 93 is one example of a second other-side bent portion.

After substrate 81 is attached to lower housing 20 (S10), one end 9A is connected to connector 83 (S20), and other end 9B is connected to connector 84 (S30), a step of attaching substrate 82 having connector 84 mounted thereon, to lower housing 20 is performed (S40). At this time, substrate 82 is attached next to substrate 81 in such a manner that connector 84 faces connector 83 in the Y direction, and substrate 82 is aligned with substrate 81 in the Y direction.

In step S40, first, substrate 82 is set at a position farther away from substrate 81 in the Y direction than the position where substrate 82 is attached to lower housing 20. At this time, fourth bent portion 94 and fifth bent portion 95 are positioned on the one side in the Z direction with respect to substrate 81, and third bent portion 93 is positioned on the other side in the Z direction with respect to substrate 81. The port of the connector 84 having other end 9B inserted thereto is positioned in a manner facing the port of connector 83 having one end 9A inserted thereto. That is, connector 84 is positioned facing connector 83 in the Y direction. Next, substrate 82 is moved closer to substrate 81 in the Y direction, while maintaining the state described above. Substrate 82 having moved next to substrate 81 in the Y direction is then attached to lower housing 20, using screws 21 (see FIG. 2).

### [Effects]

With electronic device 1 according to the exemplary embodiment, the following effects can be achieved.

If first bent portion 91 and second bent portion 92 are bent toward the same side in the Z direction, it is highly likely that first bent portion 91 and second bent portion 92 comes to the same position in the Z direction. In such a configuration, in order to avoid contact between first bent portion 91 and second bent portion 92, it is necessary to position first bent portion 91 and second bent portion 92 side by side in the Y direction so that first bent portion 91 and second bent portion 92 do not overlap each other in a view from the Z direction. That is, in this case, the distance between connector 83 and connector 84 is extended.

By contrast, according to this exemplary embodiment, first bent portion 91 and second bent portion 92 of flexible substrate 9 are bent toward the opposite sides in the Z direction. As a result, the position of first bent portion 91 in the Z direction and the position of second bent portion 92 in the Z direction can be offset from each other. Therefore, it is possible to dispose first bent portion 91 and second bent portion 92 in a manner overlapping each other in a view from the Z direction. As a result, in this exemplary embodiment, the distance between connector 83 and connector 84 can be reduced, as compared with the configuration in which first bent portion 91 and second bent portion 92 are bent to the same side in the Z direction.

According to this exemplary embodiment, flexible substrate 9 extending at second bent portion 92 toward the other side in the Z direction with respect to substrate 82 can be redirected at third bent portion 93 so as to extend toward the one side in the Z direction with respect to substrate 82.

According to this exemplary embodiment, third bent portion 93 is positioned on the side of connector 83 with respect to first bent portion 91 in the Y direction, and is positioned on the other side in the Z direction with respect to first bent portion 91. Therefore, third bent portion 93 can be disposed in a manner overlapping with first bent portion 91, in a view from the Z direction. As a result, it is possible to suppress an increase in the distance between connector 83 and connector 84 due to the presence of third bent portion 93.

In this exemplary embodiment, as portion 9D of flexible substrate 9 extending from third bent portion 93, passing through gap 20C, and extending toward the one side in the Z direction with respect to substrate 82 extends further toward the one side in the Z direction, portion 9D also shifts to a direction from substrate 81 toward substrate 82, among the Y directions. With this, it is possible to extend portion 9D of flexible substrate 9, which is a portion extending from third bent portion 93 toward the one side of substrate 82 in the Z direction, so as not to approach the portion of flexible substrate 9 extending from connector 83 (e.g., portion 9C). As a result, it is possible to reduce the possibility for portion 9D of flexible substrate 9 extending from third bent portion 93 toward the one side in the Z direction with respect to substrate 82 coming into contact with the portion of flexible substrate 9 extending from connector 83.

In this exemplary embodiment, a portion extending from connector 84 through second bent portion 92 and fourth bent portion 94, and then extending from fourth bent portion 94 delineates a Z shape. As a result, it is possible to extend portion 9D of flexible substrate 9, which is a portion extending from third bent portion 93 to fourth bent portion 94, so as not to approach portion 9C of flexible substrate 9, which is a portion extending from connector 83, through first bent portion 91, toward the one side of substrate 81 in the Z direction. As a result, it is possible to reduce the possibility that portion 9D of flexible substrate 9, which is a portion extending from third bent portion 93 to fourth bent portion 94, comes into contact with portion 9C of flexible substrate 9, which is a portion extending from connector 83, through first bent portion 91, toward the one side in the Z direction with respect to substrate 81.

In this exemplary embodiment, first bent portion 91 is bent at an acute angle. As a result, it is possible to extend portion 9C of flexible substrate 9, which is a portion extending from first bent portion 91 toward the one side of substrate 81 in the Z direction, so as not to approach the portion of flexible substrate 9 extending from connector 84 (for example, portion 9D). As a result, it is possible to reduce the possibility of portion 9C of flexible substrate 9, which is a portion extending from first bent portion 91 toward one side of substrate 81 in the Z direction, coming into contact with the portion of flexible substrate 9 extending from connector 84.

In this exemplary embodiment, a portion extending from connector 83 through first bent portion 91 and fifth bent portion 95, and then extending from fifth bent portion 95 delineates a Z shape. As a result, it is possible to extend portion 9C of flexible substrate 9, which is a portion extending from first bent portion 91 to fifth bent portion 95, so as not to approach portion 9D of flexible substrate 9, which is a portion extending from connector 84, through third bent portion 93, toward one side of substrate 82 in the Z direction. As a result, it is possible to reduce the possibility of portion 9C of flexible substrate 9, which is a portion extending from first bent portion 91 to fifth bent portion 95, coming into contact with portion 9D of flexible substrate 9, which is a portion extending from connector 84 through third bent portion 93 toward one side of substrate 82 in the Z direction.

If the position of substrate 82 in the Z direction is on the one side in the Z direction with respect to substrate 81, a portion of flexible substrate 9 extending from connector 83 through first bent portion 91 toward the one side of substrate 81 in the Z direction is likely to come into contact with third bent portion 93 or the like. However, because the position of substrate 82 in the Z direction is the same as or substantially the same as the position of substrate 81 in the Z direction, or on the other side of substrate 81 in the Z direction, it is possible to suppress the possibility of the contact described above.

Because first bent portion 91 and second bent portion 92 of flexible substrate 9 are bent toward the opposite sides in the Z direction, it is possible to set the distance between connector 83 and connector 84 in the Y direction to 10 (mm) or less, as in this exemplary embodiment.

With such a production method, substrate 81 and substrate 82 can be easily attached to lower housing 20, in the configuration in which first bent portion 91 and second bent portion 92 are bent toward the opposite sides in the Z direction.

Note that, in this exemplary embodiment, an example in which electronic device 1 is a laptop PC has been described, but the present disclosure is not limited thereto. The electronic device 1 may be any device that includes two substrates and a flexible substrate connecting the two substrates.

In this exemplary embodiment, an example in which flexible substrate 9 has five bent portions has been described, but the number of bent portions is not limited to five. Furthermore, the shape of flexible substrate 9 is not limited to the shape illustrated in FIG. 4 and the like. Flexible substrate 9 may be configured in any way as long as the portion extending from connector 83 and the portion extending from connector 84 are bent toward the opposite sides in the Z direction. For example, it is possible for flexible substrate 9 not to include fifth bent portion 95. In this case, flexible substrate 9 is bent only at one position (fourth bent portion 94) on the one side of substrates 81, 82 in the Z direction. Furthermore, for example, it is also possible for the portion of flexible substrate 9 extending from connector 83 through first bent portion 91 and fifth bent portion 95, and then extending from fifth bent portion 95 not to delineate a Z shape, in a view from the X direction.

Described in this exemplary embodiment is an example in which each of first bent portion 91, fourth bent portion 94, and fifth bent portion 95 of flexible substrate 9 is bent at an acute angle has been described, but the angle at which each of the bent portions including second bent portion 92 and third bent portion 93 is bent is not limited thereto. For example, first bent portion 91 may be bent at a right angle or an obtuse angle. That is, angle θ1 may be a right angle or an obtuse angle.

Described in the present exemplary embodiment is an example in which flexible substrate 9 extending from connector 83 is bent toward the one side in the Z direction at first bent portion 91, and flexible substrate 9 extending from connector 84 is bent toward the other side in the Z direction at second bent portion 92, but the present invention is not limited thereto. For example, reversely to the configuration described above, flexible substrate 9 extending from connector 83 may be bent toward the other side in the Z direction at first bent portion 91, and flexible substrate 9 extending from connector 84 may be bent toward the one side in the Z direction at second bent portion 92. In this case, third bent portion 93 is positioned on the one side of substrate 82 in the Z direction, and fourth bent portion 94 and fifth bent portion 95 are positioned on the other side of substrate 81 in the Z direction.

Described in the production method for electronic device 1 according to this exemplary embodiment is an example in which flexible substrate 9 is bent in advance and has five bent portions, but the present disclosure is not limited thereto. For example, it is possible for second bent portion 92 of flexible substrate 9 not to be bent in advance. In such a case, flexible substrate 9 is bent in advance at the bent portions (first bent portion 91, third bent portion 93, fourth bent portion 94, and fifth bent portion 95), but does not have second bent portion 92. Second bent portion 92 is formed between other end 9B and third bent portion 93 naturally or by a user or the like, during the process of performing the final step of the production method for electronic device 1, that is, the step of attaching substrate 82 to lower housing 20.

The “bending” in this exemplary embodiment is not limited to a folded configuration, and includes gently curved configuration (in other words, a curved configuration).

Although the present disclosure has been fully described with reference to a preferred exemplary embodiment and with reference to the accompanying drawings, various variations and modifications will become apparent to those skilled in the art. Such variations and modifications are to be understood as being included within the scope of the present disclosure as set forth in the appended claims, unless departing from the scope of the present disclosure.

### Outlines of Exemplary Embodiment

(1) An electronic device according to the present disclosure includes: a first substrate on which a first connector is mounted; a second substrate that is disposed with a gap with respect to the first substrate in a first direction, and on which a second connector is mounted; and a flexible substrate having one end and another end, with the one end being connected to the first connector, and the other end being connected to the second connector, in which the first connector and the second connector face each other in the first direction; the flexible substrate further includes a first bent portion, and a second bent portion that is positioned on a side nearer to the other end than the first bent portion; the flexible substrate extending from the first connector is bent at the first bent portion toward one side in a second direction that is orthogonal to the first direction, and extends further toward the one side in the second direction with respect to the first substrate; and the flexible substrate extending from the second connector is bent at the second bent portion toward another side in the second direction, and extends further toward the other side in the second direction with respect to the second substrate.
(2) In the electronic device according to (1), the flexible substrate may further include a third bent portion on the other side in the second direction with respect to the second substrate, and between the first bent portion and the second bent portion, and the flexible substrate extending from the second bent portion toward the other side in the second direction with respect to the second substrate may be bent at the third bent portion toward the one side in the second direction, pass through a gap between the first substrate and the second substrate, and extend toward the one side in the second direction with respect to the second substrate.
(3) In the electronic device according to (2), the third bent portion may be positioned on a side nearer to the first connector in the first direction with respect to the first bent portion, and may be positioned on the other side in the second direction with respect to the first bent portion.
(4) In the electronic device according to (2) or (3), the first direction may be a direction from the second substrate toward the first substrate, and as a portion of the flexible substrate extending from the third bent portion, passing through the gap, and extending toward the one side in the second direction with respect to the second substrate extends further toward the one side in the second direction, the portion may shift to a direction opposite to the first direction.
(5) In the electronic device according to (4), the flexible substrate may further include a fourth bent portion on the one side in the second direction with respect to the second substrate and between the third bent portion and the first bent portion, the flexible substrate extending from the third bent portion toward the one side in the second direction with respect to the second substrate may be bent at the fourth bent portion at an acute angle and extend in the first direction, and a portion of the flexible substrate extending from the second connector through the second bent portion and the fourth bent portion, and then extending from the fourth bent portion may delineate a Z shape in a view from a third direction orthogonal to the first direction and the second direction.
(6) In the electronic device according to any one of (1) to (5), the first bent portion may be bent at an acute angle.
(7) In the electronic device according to (6), the first direction may be a direction from the second substrate toward the first substrate; the flexible substrate may further include a fifth bent portion on the one side in the second direction with respect to the first substrate and between the first bent portion and the second bent portion; the flexible substrate extending from the first bent portion toward the one side in the second direction with respect to the first substrate may be bent at the fifth bent portion at an acute angle and extend in a direction opposite to the first direction; and a portion of the flexible substrate extending from the first connector through the first bent portion and the fifth bent portion, and then extending from the fifth bent portion may delineate a Z shape in a view from a third direction orthogonal to the first direction and the second direction.
(8) In the electronic device according to any one of (1) to (7), a position of the second substrate in the second direction may be same as or substantially same as a position of the first substrate in the second direction, or may be a position on the other side in the second direction with respect to the first substrate.
(9) In the electronic device according to any one of (1) to (8), a distance between the first connector and the second connector in the first direction may be 10 (mm) or less.
(10) A production method for an electronic device according to an aspect of the present disclosure includes: a step of attaching a first substrate to a housing; a step of connecting one end of a flexible substrate to a first connector mounted on the first substrate; a step of connecting another end of the flexible substrate to a second connector mounted on a second substrate, in which the flexible substrate includes: one principal surface; another principal surface that is on a rear side of the one principal surface; at least one one-side bent portion having a concave on the one principal surface; a first other-side bent portion provided between the one-side bent portion and the one end, and having a concave on the other principal surface; and a second other-side bent portion provided between the one-side bent portion and the other end, and having a concave on the other principal surface, after the first substrate is attached to the housing and the one end is connected to the first connector, the one principal surface or the other principal surface of the flexible substrate faces the housing, the production method further includes a step of attaching the second substrate next to the first substrate in the housing so that the first connector and the second connector face each other in a first direction, after the first substrate is attached to the housing, the one end is connected to the first connector, and the other end is connected to the second connector, and when the second substrate is attached to the housing, the second substrate is attached to the housing by being brought nearer to the first substrate in the first direction in such a manner that the one-side bent portion is positioned on one side in a second direction orthogonal to the first direction, with respect to the first substrate, and the second other-side bent portion is positioned on another side in the second direction with respect to the first substrate.

### INDUSTRIAL APPLICABILITY

The present disclosure is useful for an electronic device (such as a laptop PC) in which a plurality of printed boards are connected by a flexible substrate.

### REFERENCE MARKS IN THE DRAWINGS

1 electronic device
9 flexible substrate
9A one end
9B other end
9E one principal surface
9F other principal surface
20 lower housing (housing)
20C gap
81 substrate (first substrate)
82 substrate (second substrate)
83 connector (first connector)
84 connector (second connector)
91 first bent portion (first other-side bent portion)
92 second bent portion
93 third bent portion (second other-side bent portion)
94 fourth bent portion (one-side bent portion)
95 fifth bent portion (one-side bent portion)

1. An electronic device comprising:
a first substrate on which a first connector is mounted;
a second substrate that is disposed with a gap with respect to the first substrate in a first direction, and on which a second connector is mounted; and
a flexible substrate having one end and another end, with the one end being connected to the first connector, and the other end being connected to the second connector, wherein
the first connector and the second connector face each other in the first direction,
the flexible substrate further includes a first bent portion, and a second bent portion that is positioned on a side nearer to the other end than the first bent portion,
the flexible substrate extending from the first connector is bent at the first bent portion toward one side in a second direction that is orthogonal to the first direction, and extends further toward the one side in the second direction with respect to the first substrate, and
the flexible substrate extending from the second connector is bent at the second bent portion toward another side in the second direction, and extends further toward the other side in the second direction with respect to the second substrate.

2. The electronic device according to claim 1, wherein
the flexible substrate further includes a third bent portion on the other side in the second direction with respect to the second substrate, and between the first bent portion and the second bent portion, and
the flexible substrate extending from the second bent portion toward the other side in the second direction with respect to the second substrate is bent at the third bent portion toward the one side in the second direction, passes through a gap between the first substrate and the second substrate, and extends toward the one side in the second direction with respect to the second substrate.

3. The electronic device according to claim 2, wherein the third bent portion is positioned on a side nearer to the first connector in the first direction with respect to the first bent portion, and is positioned on the other side in the second direction with respect to the first bent portion.

4. The electronic device according to claim 2, wherein
the first direction is a direction from the second substrate toward the first substrate, and
as a portion of the flexible substrate extending from the third bent portion, passing through the gap, and extending toward the one side in the second direction with respect to the second substrate extends further toward the one side in the second direction, the portion shifts to a direction opposite to the first direction.

5. The electronic device according to claim 4, wherein
the flexible substrate further includes a fourth bent portion on the one side in the second direction with respect to the second substrate and between the third bent portion and the first bent portion,
the flexible substrate extending from the third bent portion toward the one side in the second direction with respect to the second substrate is bent at the fourth bent portion at an acute angle and extends in the first direction, and
a portion of the flexible substrate extending from the second connector through the second bent portion and the fourth bent portion, and then extending from the fourth bent portion delineates a Z shape in a view from a third direction orthogonal to the first direction and the second direction.

6. The electronic device according to claim 1, wherein the first bent portion is bent at an acute angle.

7. The electronic device according to claim 6, wherein
the first direction is a direction from the second substrate toward the first substrate,
the flexible substrate further includes a fifth bent portion on the one side in the second direction with respect to the first substrate and between the first bent portion and the second bent portion,
the flexible substrate extending from the first bent portion toward the one side in the second direction with respect to the first substrate is bent at the fifth bent portion at an acute angle and extends in a direction opposite to the first direction, and
a portion of the flexible substrate extending from the first connector through the first bent portion and the fifth bent portion, and then extending from the fifth bent portion delineates a Z shape in a view from a third direction orthogonal to the first direction and the second direction.

8. The electronic device according to claim 1, wherein a position of the second substrate in the second direction is same as or substantially same as a position of the first substrate in the second direction, or is a position on the other side in the second direction with respect to the first substrate.

9. The electronic device according to claim 1, wherein a distance between the first connector and the second connector in the first direction is 10 (mm) or less.

10. A production method for an electronic device, the production method comprising:
a step of attaching a first substrate to a housing;
a step of connecting one end of a flexible substrate to a first connector mounted on the first substrate;
a step of connecting another end of the flexible substrate to a second connector mounted on a second substrate, wherein
the flexible substrate includes:
one principal surface;
another principal surface that is on a rear side of the one principal surface;
at least one one-side bent portion having a concave on the one principal surface;
a first other-side bent portion provided between the one-side bent portion and the one end, and having a concave on the other principal surface; and
a second other-side bent portion provided between the one-side bent portion and the other end, and having a concave on the other principal surface,
after the first substrate is attached to the housing and the one end is connected to the first connector, the one principal surface or the other principal surface of the flexible substrate faces the housing,
the production method further comprises a step of attaching the second substrate next to the first substrate in the housing so that the first connector and the second connector face each other in a first direction, after the first substrate is attached to the housing, the one end is connected to the first connector, and the other end is connected to the second connector, and
when the second substrate is attached to the housing, the second substrate is attached to the housing by being brought nearer to the first substrate in the first direction in such a manner that the one-side bent portion is positioned on one side in a second direction orthogonal to the first direction, with respect to the first substrate, and the second other-side bent portion is positioned on another side in the second direction with respect to the first substrate.
